(19) United States
(12) Patent Application Publication
(10) Pub. No.: US 2026/0063984 A1
(43) Pub. Date: Mar. 5, 2026

(54) OPTICAL PROXIMITY CORRECTION METHOD AND MASK MANUFACTURING METHOD INCLUDING THE OPC METHOD

(71) Applicant: SAMSUNG ELECTRONICS CO., LTD., Suwon-si (KR)

(72) Inventors: Sujin OH, Suwon-si (KR); Sanghun KIM, Suwon-si (KR); Jinseok OH, Suwon-si (KR)

(73) Assignee: SAMSUNG ELECTRONICS CO., LTD., Suwon-si (KR)

(21) Appl. No.: 19/191,497

(22) Filed: Apr. 28, 2025

(30) Foreign Application Priority Data
Aug. 28, 2024 (KR) 10-2024-0116003

(51) Int. Cl. G03F 1/36

(52) U.S. Cl. CPC G03F 1/36

(57) ABSTRACT

Provided is an optical proximity correction (OPC) method. The OPC method includes inputting an OPC target design layout, dividing edges of an input OPC target design layout into a plurality of segments, setting a direction of progression of the segments, measuring angles of the segments with respect to the direction of progression, setting a mode for adding vertices according to angles measured in the measuring, adding vertices according to a set mode, adding at least one fake segment extending to an added vertex, and performing OPC based on an added fake segment.

### CROSS-REFERENCE TO RELATED APPLICATION

This application is based on and claims priority under 35 U.S.C. § 119 to Korean Patent Application No. 10-2024-0116003, filed on Aug. 28, 2024, in the Korean Intellectual Property Office, the disclosure of which is incorporated by reference herein in its entirety.

### BACKGROUND

The disclosure relates to an optical proximity correction (OPC) method and a mask manufacturing method using the OPC method.

In a method of manufacturing a semiconductor device, a photolithography process using a mask may be performed to form a pattern on a semiconductor substrate, such as a wafer. A mask may be simply defined as a pattern transfer material in which a pattern shape of an opaque material is formed on a transparent base material. In a mask manufacturing process, a desired circuit is designed, a layout for the desired circuit is designed, and design data is obtained through OPC for the designed layout, and the design data is transmitted as mask tape-out (MTO) design data. Thereafter, mask data preparation (MDP) may be performed based on the MTO design data, and an exposure process, etc. may be performed on a mask substrate.

### SUMMARY

The disclosure provides an optical proximity correction (OPC) method with improved reliability.

The disclosure also provides a mask manufacturing method including an OPC method.

According to an aspect of the disclosure, there is provided an optical proximity correction (OPC) method including: obtaining an OPC target design layout; dividing one or more edges of the OPC target design layout into a plurality of segments; setting a direction of progression of the plurality of segments; measuring angles of the plurality of segments with respect to the direction of progression; setting a mode for adding vertices based on the angles of the plurality of segments; adding the vertices based on the mode; adding at least one fake segment extending to an added vertex, among the vertices; and performing OPC based on the at least one fake segment.

According to an aspect of the disclosure, there is provided an optical proximity correction (OPC) method including: obtaining an OPC target design layout; dividing one or more edges of the OPC target design layout into a plurality of segments; setting a direction of progression of the plurality of segments; measuring angles of the plurality of segments with respect to the direction of progression; setting a mode for adding vertices based on the angles of the plurality of segments; adding the vertices based on the mode; adding at least one fake segment extending to an added vertex, among the vertices; and performing a Manhattan OPC based on the least one fake segment, wherein the at least one fake segment is added in a normal direction to one of both ends, a start point, and an end point of a segment, among the plurality of segments, and wherein the measuring of the angles of the segments with respect to the direction of progression includes determining whether an angle of a corner bending is 2n times 45°, where n is an integer, based on the direction of progression of the segments.

According to an aspect of the disclosure, there is provided a mask manufacturing method including: obtaining an OPC target design layout; dividing one or more edges of the OPC target design layout into a plurality of segments; setting a direction of progression of the plurality of segments; measuring angles of the plurality of segments with respect to the direction of progression; setting a mode for adding vertices based on the angles of the plurality of segments; adding the vertices based on the mode; adding at least one fake segment extending to an added vertex, among the vertices; performing a Manhattan OPC based on the at least one fake segment; transmitting data regarding a final optical proximity corrected Manhattan design layout as mask tape-out (MTO) design data; preparing mask data based on the MTO design data; and performing exposure on a mask substrate, based on the mask data, wherein the at least one fake segment is added in a normal direction of one of both ends, a start point, and an end point of a segment, among the plurality of segments, wherein the measuring the angles of the plurality of segments with respect to the direction of progression includes determining whether an angle of a corner bending is 2n times 45°, where n is an integer, based on the direction of progression of the plurality of segments, wherein the mode for adding the vertices includes one of: a start mode for adding a vertex to a start point of a segment, based on the direction of progression of the segments; an end mode for adding a vertex to an end point of the segment, based on the direction of progression of the segments; and a dual mode for adding vertices to the start point and the end point of the segment, wherein based on the start point and the end point of each of the plurality of segments being first vertices and dissection points added in the adding of the vertices being second vertices, the at least one fake segment extends to a second vertex corresponding to a first vertex, and wherein the first vertex is or corresponds to one of the first vertices, and the second vertex is or corresponds to one of the second vertices.

### BRIEF DESCRIPTION OF DRAWINGS

Embodiments of the disclosure will be more clearly understood from the following detailed description taken in conjunction with the accompanying diagrams in which:

FIG. 1 is a flowchart of an optical proximity correction (OPC) method according to an embodiment;

FIG. 2 is a flowchart of an OPC method according to another embodiment;

FIG. 3 is a flowchart of an OPC method according to another embodiment;

FIGS. 4A, 4B, 5, 6 and 7 are conceptual diagrams illustrating operations of adding vertices and fake segments in the OPC method of FIG. 1;

FIG. 8A is a conceptual diagram illustrating how OPC is performed while maintaining mask rule check (MRC);

FIG. 8B is a conceptual diagram illustrating a result of performing the Manhattan OPC without maintaining MRC;

FIG. 8C is a conceptual diagram illustrating a result of performing an OPC based on added fake segments in an OPC method, according to an embodiment;

FIG. 9 is a conceptual diagram illustrating corner EPE values for respective cases;

FIG. 10 is a table showing runtimes, output memories, and corner EPE values for respective cases; and

FIG. 11 is a schematic flowchart of operations of a mask manufacturing method including an OPC method, according to an embodiment.

### DETAILED DESCRIPTION

Below, embodiments of the disclosure will be described in detail and clearly to such an extent that an ordinary one in the art easily carries out the disclosure. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

To clearly describe the disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description, the disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

According to one or more embodiments, various operations and/or functions described below may be implemented in a hardware approach. For example, according to some embodiments, the methods described below may be implemented by an electronic device configured to carry out a described operation(s) or function(s). The electronic device may include blocks, which may be referred to herein as managers, units, modules, hardware components, “˜er” terms or the like, may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure. However, the disclosure is not limited thereto, and as such, the blocks, which may be referred to herein as managers, units, modules, or the like, may be software modules implemented by software codes, program codes, software instructions, or the like. The software modules may be executed on one or more processors.

According to one or more embodiments, various methods, operations and/or functions described below may be implemented or supported by artificial intelligence technology or one or more computer programs, each of which is configured with computer-readable program code and executed on a computer-readable medium. The term “computer-readable medium” includes any type of medium that may be accessed by a computer, such as read-only memory (ROM), random-access memory (RAM), a hard disk drive, a compact disc (CD), a digital video disc (DVD), or other types of memory. A “non-transitory” computer-readable medium excludes wired, wireless, optical, or other communication links that transmit transitory electrical signals or other signals. The non-transitory computer-readable medium includes a medium in which data can be permanently stored, and a medium in which data can be stored and later overwritten, such as a rewritable optical disk or an erasable memory device.

Hereinafter, embodiments are described in detail with reference to the attached drawings.

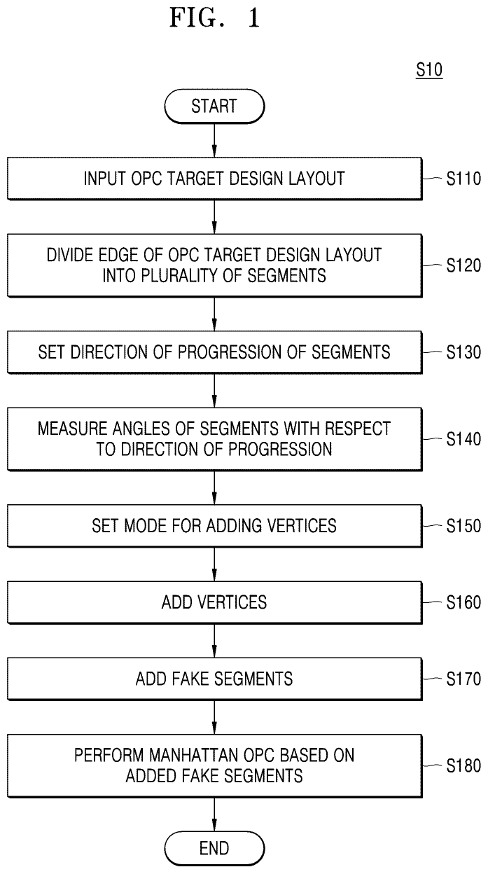

FIG. 1 is a flowchart of an optical proximity correction (OPC) method according to an embodiment.

Referring to FIG. 1, an OPC method S10 may include an operation S110 of inputting a layout of an OPC target design. Here, the OPC target design layout may refer to a design layout for a target pattern to be formed on a substrate such as a wafer. Here, an OPC target design may refer to a layout of a target to perform OPC. A target pattern on a substrate may be formed by transferring a pattern on a mask to the substrate through an exposure process. According to an embodiment, the OPC target design layout may refer to a layout for the pattern on the mask corresponding to the target pattern on the substrate. Since a pattern on a mask is scaled down and projected onto a wafer, the pattern on the mask may have a larger size than a target pattern on a substrate.

In operation S120, the OPC method S10 may include dividing edges of the OPC target design layout input in operation S110 into a plurality of segments. According to an embodiment, the lengths of the edges may be same or different from each other. An edge may be a part corresponding to a bent corner. According to an embodiment, the plurality of segments may be straight lines or the plurality of segments may be corners that include bent portions.

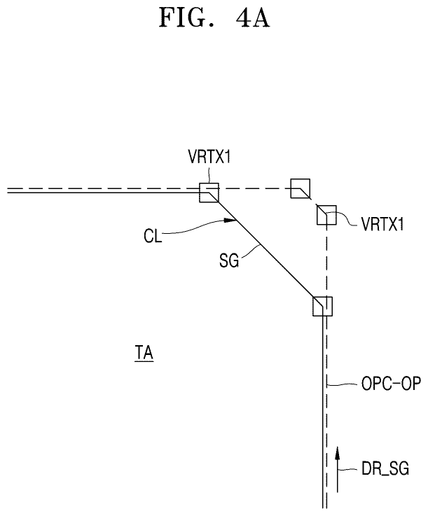

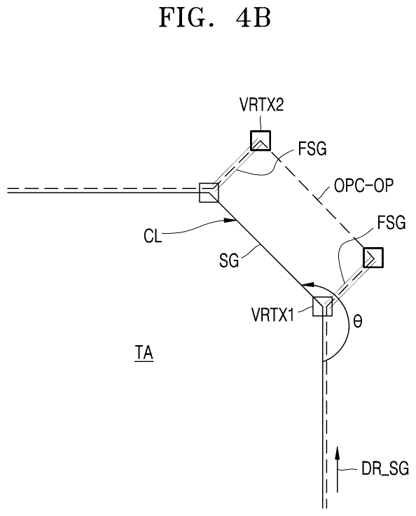

In operation S130, the OPC method S10 may include setting a direction of progression of the segments divided in operation S120. The direction of progression of the segments may be a direction used to determine a start point and an end point when selecting points to add vertices or fake segments (e.g., FSG of FIG. 4B) to be described later. The fake segment may also be referred to as a dummy segment. The direction of progression may also be a direction clockwise around a target. The direction of progression may also be a direction counterclockwise around a target. According to an embodiment, for one target, the direction of progression may be fixed to one direction.

According to an embodiment, the OPC method S10 may measure an angle for the direction of progression of each segment while proceeding in the direction set in operation S130. An angle for a direction of progression refers to an angle between segments divided in the direction of progression. The angle may be measured in a direction toward the optical proximity corrected (hereinafter “OPC-ed”) design layout, in the direction of progression. The angle may be measured outward from a target in the direction of progression. A measured angle may be in the clockwise direction or the counterclockwise direction, but is not limited to any one of them.

In operation S150, the OPC method S10 may include setting a mode for adding a vertex, based on the angle measured in operation S140. According to an embodiment, a vertex may refer to one of corners or a portion of a segment. According to an embodiment, an added vertex may mean a new point other than a vertex and one of the regions inside the segment divided in operation S120. A vertex, which is one point of a segment of a target, may be referred to as a first vertex (e.g., VRTX1 of FIG. 4B). Operation S150 is an operation of setting a mode of adding a second vertex (e.g., VRTX2 of FIG. 4B) to be added in operation S160. In operation S150, the second vertex is not added, and only the mode of adding the second vertex may be set. A plurality of modes may be set in operation S150.

In operation S160, the OPC method S10 may include adding vertices based on a mode set in operation S150. For example, a vertex added at operation S160 may be referred to as the second vertex. For example, a vertex added to a new point in operation S160 may be a new dissection point. The second vertex is a different vertex from the first vertex. According to an embodiment, one or more second vertices may be added in correspondence to the first vertex. The first vertex may be a reference point for adding one or more second vertices. For example, first vertices may be located at both end of a segment. An example case in which one second vertex is added in correspondence to the first vertex and an example case in which two second vertices are added in correspondence to the first vertex are described in detail below.

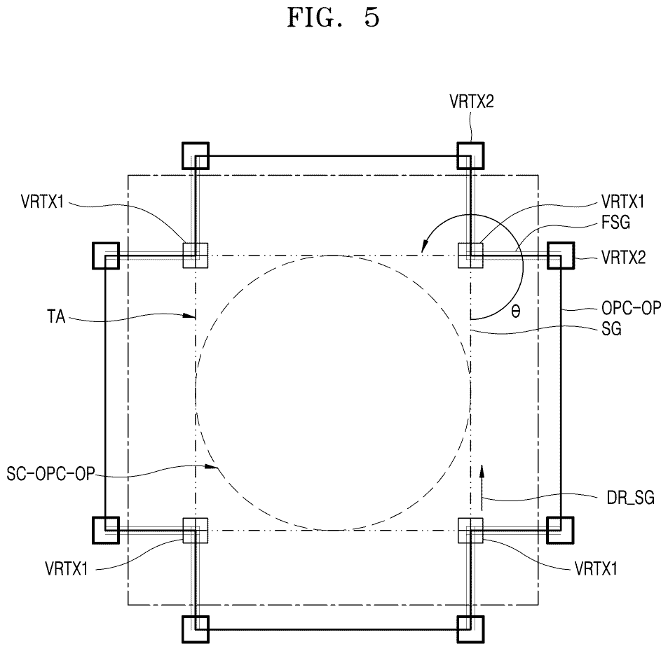

In operation S170, the OPC method S10 may include adding a fake segment extending to a vertex added in operation S160. The fake segment (e.g., FSG of FIG. 4B) added in operation S170 may be a straight line. For example, the fake segment may extend from the first vertex (e.g., VRTX1 of FIG. 4B) to the second vertex (e.g., VRTX2 of FIG. 4B). The start point of the fake segment may be the first vertex, and the end point of the fake segment may be the second vertex. The start points of a plurality of fake segments (e.g., two FSGs of FIG. 4B) may be the same. In an example case in which the start points of a plurality of fake segments are the same, two second vertices may be formed for one first vertex. An example case in which the start points of a plurality of fake segments are the same is described below in detail with reference to FIG. 5. According to an embodiment, a plurality of fake segments may be added for one target. The fake segments added in operation S170 may have lengths that are same as each other or different from each other.

In operation S180, the OPC method S10 may include performing Manhattan OPC based on the fake segments added in operation S170. According to an embodiment, the Manhattan OPC may be a method of maintaining the linearity and the orthogonal structure of a pattern in a semiconductor manufacturing process. In the Manhattan OPC, a pattern may include straight lines and right angles only. In the Manhattan OPC, diagonal patterns or curved patterns may not be formed. In other words, in the Manhattan OPC, a pattern may be corrected by forming the pattern with vertical lines and horizontal lines only. This simplifies the pattern and facilitates correction and implementation of the pattern in a lithography process. Also, since a pattern includes only right angles in the Manhattan OPC according to an embodiment, the difference between a pattern at the design stage and an actually manufactured pattern may be minimized, thereby increasing predictability in the manufacturing process. According to an embodiment, one or more operations may be added, or omitted from the operations illustrated in FIG. 1. According to an embodiment, one or more operations illustrated in FIG. 1 may be performed simultaneously, sequentially or in a different order.

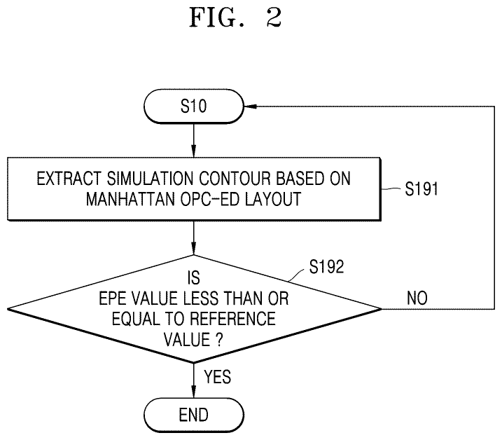

FIG. 2 is a flowchart of an OPC method according to another embodiment.

Referring to FIG. 2 together with FIG. 1, the OPC method S10 may be performed a plurality of number of times. For example, after performing the OPC method S10, in operation S191, the OPC method may include extracting a simulation contour, based on a Manhattan OPC layout. In operation S192, the OPC method may include determining whether an edge placement edge (EPE) value is less than or equal to a reference value may be performed. The reference value may be a preset value. In an example case in which the EPE value is not less than the reference value in operation S192, the OPC method S10 may be performed again. According to an embodiment, the shape of the initial simulation contour extracted after operation S191 is performed for the first time may deviate significantly from the shape of a target pattern. Therefore, to minimize the difference, the simulation contour is compared to the target pattern, and the positions of segments of an OPC target design layout are changed to generate a new OPC design layout. According to an embodiment, data for the new OPC design layout may be input into an OPC model, and a simulation contour may be extracted again through a simulation. For example, the operation of comparing the simulation contour to the target pattern and adjusting segments may be performed again to generate an OPC design layout again. This process may be repeated until a set condition is satisfied. For example, a condition may be set based on the EPE value as in operation S192 or the number of repetitions. In other words, the process for simulation contour extraction may be repeated until the EPE value becomes lower than a set reference value or the number of repetitions reaches a set reference number. Here, the EPE may mean the difference between a simulation contour and a target pattern at an evaluation point. Also, a reference number may be set based on the average number of times or the maximum number of times that the EPE reaches the reference value through simulation using an OPC model. Ultimately, an OPC design layout finally generated through the repetition of the process corresponds to an OPC-ed design layout, and may correspond to an OPC-ed design layout (OPC-OP of FIG. 5) in the OPC method of the present embodiment.

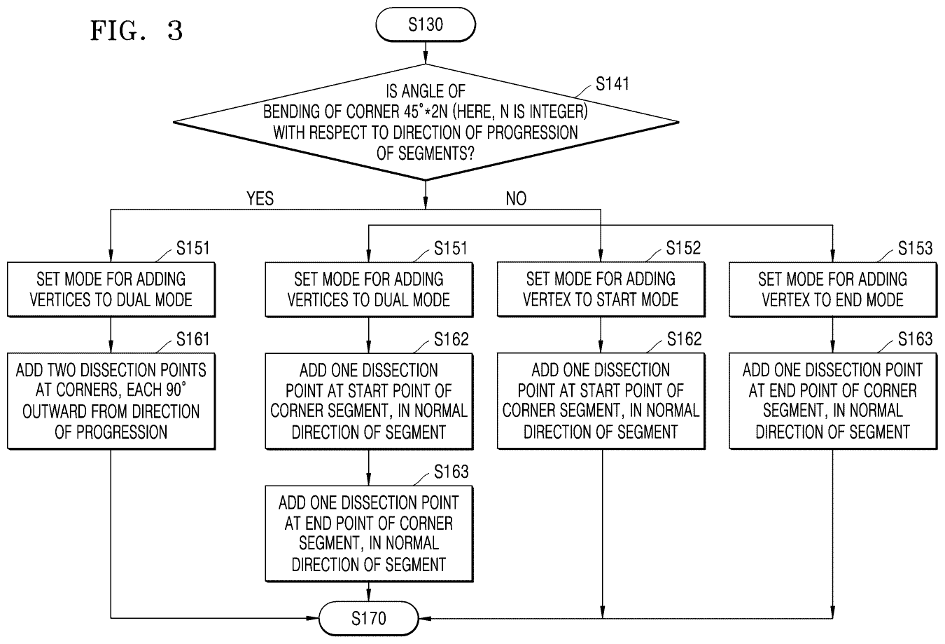

FIG. 3 is a flowchart of an OPC method according to another embodiment.

Referring to FIG. 3 together with FIG. 1, in operation S140, the method may include operation S141 of determining whether the angle of a corner bend is 2n times 45° (where n is an integer) based on the direction of progression of segments. For example, operation S140 may be an operation of determining whether the angle of the corner bend is an odd multiple or an even multiple of 45°. In an example case in which the angle of the corner bend is an even multiple of 45°, the angle of the corner bend may be one of 0°, 90°, 180°, 270°, and 360°. In other words, segments may be orthogonal and connected to each other or connected to each other in a straight line. In an example case in which the angle of the corner bend is an odd multiple of 45°, the angle of the corner bend may be one of 45°, 135°, 225°, and 315°. Angles formed by segments may include not only acute angles, but also right angles and obtuse angles.

In operation S150, the method may include operation S151, operation S152 or operation S153. For example, operation S151 corresponds to a dual mode for adding vertices to the start point and the end point of the segment based on the direction of progression of the segment, operation S152 corresponds to ha start mode for adding a vertex to the start point of the segment based on the progress direction of the segment, and operation S153 corresponds to an end mode for adding a vertex to the end point of the segment based on the progress direction of the segment.

As described above, according to an embodiment, in operations S151, S152, and S153, only modes are set for adding vertices, and no vertices may not be actually added yet. According to an embodiment, selecting a mode for adding a vertex may correspond to selecting a point for the first vertex (e.g., VRTX1 of FIG. 4B). According to an embodiment, two first vertices may be set for one segment in operation S151, but one first vertex may be set for one segment in each of operations S152 and S153. According to an embodiment, the second vertices (e.g., VRTX2 of FIG. 4B) may be added in operation S160 in correspondence to the first vertices (VRTX1 of FIG. 4B) set in operations S151, S152, and S153.

In operation S160, the method may include operation S161, operation S162 and operation 162. According to an embodiment, operation S161 may include adding two dissection points at corners, each 90° outward from the direction of progression. The dissection points in operation S161 may be the second vertices (VRTX2 of FIG. 4B) as described above.

According to an embodiment, operation S161 may be performed only when the angle of the corner bending with respect to the direction of progression of segments in operation S141 is an even multiple of 45°. A corner in operation S161 may correspond to a vertex of a target. Corners here may correspond to both ends of a segment. Detailed descriptions thereof will be given below with reference to FIG. 5.

According to an embodiment, operation S162 may include adding one dissection point at the start point of a corner segment, in a normal direction of the corner segment. According to an embodiment, a corner segment may correspond to a segment. However, a corner segment may refer to a segment located at a corner from among segments. According to an embodiment, a normal direction may refer to a direction perpendicular to the direction of progression of a segment. For example, the normal direction may refer to the outer vertical direction from among vertical directions. According to an embodiment, operation S163 may include adding one dissection point at the end point of the corner segment, in the normal direction of the corner segment. Operation S163 is identical to operation S162 except points of adding dissection points, and thus detailed descriptions thereof will be omitted.

In an example case in which operation S151 is performed, operations S162 and S163 may be performed sequentially as well as operation S161. According to an embodiment, operations S162 and S163 may be sequentially performed only when the angle of the corner bending is an odd multiple of 45° with respect to the direction of progression of the segments. Operation S162 may also be performed after operation S152. Operation S163 may also be performed after operation S153. Operations S152 and S153 may be performed when the angle of the corner bending is an odd multiple of 45° with respect to the direction of progression of the segments.

The start point and the end point of a segment may be referred to as first vertices, and dissection points added in operations S161 to S163 may be referred to as second vertices. A fake segment may extend from a first vertex to a second vertex corresponding to the first vertex.

FIGS. 4A, 4B, 5, 6, and 7 are conceptual diagrams illustrating operations of adding vertices and fake segments in the OPC method of FIG. 1.

FIG. 4A illustrates a related art Manhattan OPC, and FIG. 4B illustrates a Manhattan OPC according to an embodiment of the disclosure. In each of the cases illustrated in FIGS. 4A and 4B, a target TA may be provided. The target TA may be a wafer. Some corners of the target TA may be dissected. A portion being dissected may be referred to as a chopping layer CL. Angles at which chopping layers CL are formed may be different from each other. Layouts regarding the outer circumferential surface of the target TA may be separated into a plurality of segments SG in operation S120. For example, a corner segment located at a corner of the chopping layer CL may be separated into one segment SG. A direction segment DR_SG for performing OPC for separated segments SG may be set in operation S130. As illustrated in FIGS. 4A and 4B, the direction segment DR_SG starts from the bottom of the target TA and may be set counterclockwise along the outer circumferential surface of the target TA. The start point and the end point of the segment SG may be designated as first vertices VRTX1.

In FIG. 4A, while no additional vertices are designated and the number of segments remains unchanged, the OPC-ed design layout OPC-OP extends at corner portions, and, it may be confirmed that, when the angle of a corner is 45°, a corner-side of the OPC-ed design layout OPC-OP becomes shorter. In this case, the fake segment FSG may extend only to the extent that the extension does not violate the Mask Rule Check (MRC).

In FIG. 4B, corresponding second vertices VRTX2 may correspond to the first vertices VRTX1. Also, as in operation S140, an angle θ between the segments SG in the direction in which the segments SG are bent may be measured. Depending on whether the angle θ is an odd multiple or an even multiple of 45°, the aspect of second vertices added may differ. A fake segment FSG may be provided between a first vertex VRTX1 and a second vertex VRTX2. By generating fake segments FSG, the degree of freedom of OPC in corner regions may be improved without violating the MRC.

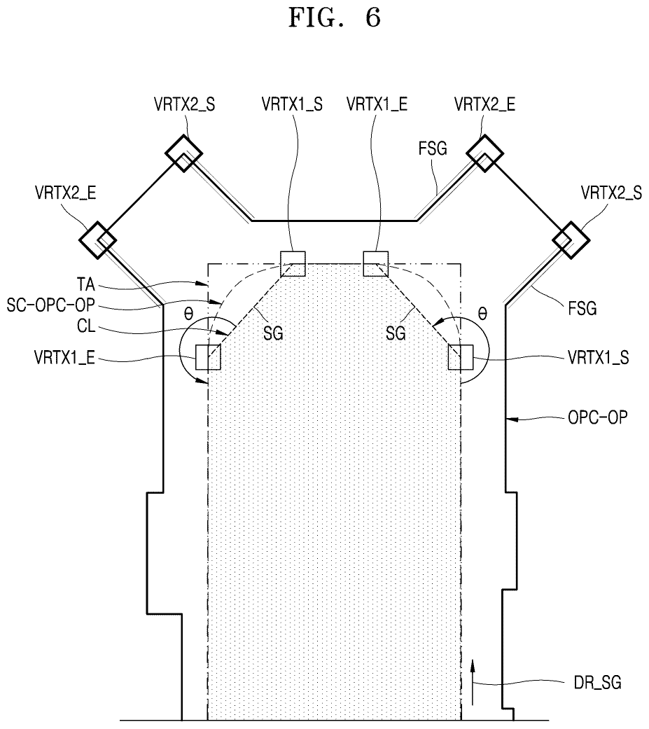

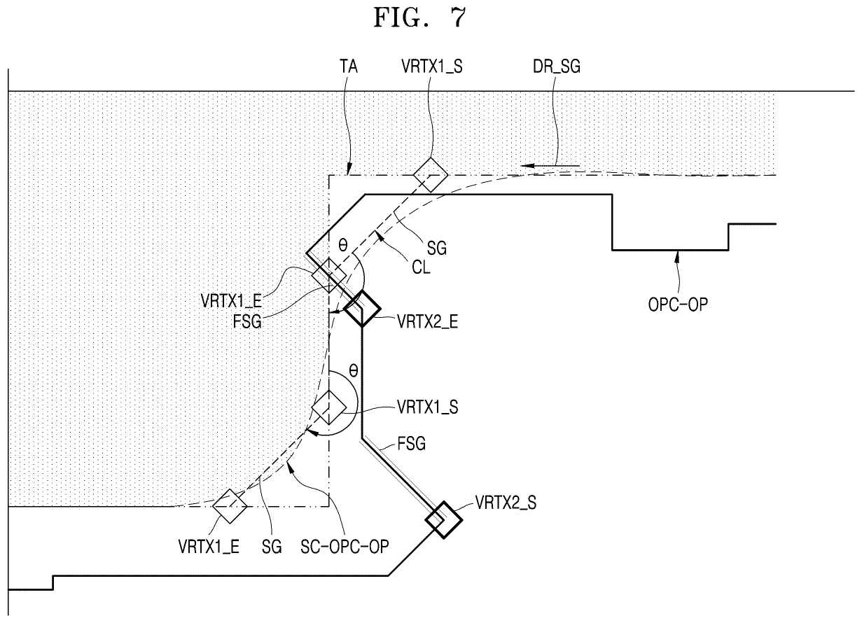

Referring to FIG. 5 together with FIGS. 1 to 3, the target TA may be indicated by a two-dotted chain line. The dashed dotted line may be a reference line. The bold solid line is the OPC-ed design layout OPC-OP. The circular shape indicated by a dotted line in the middle may be a simulation contour SC-OPC-OP extracted in operation S191. The same applies to FIGS. 6 and 7 below. No chopping layer may be formed at corners of the target TA. In the case of FIG. 5, the direction segment DR_SG may be a counterclockwise direction. Both ends of the segments SG may be defined. The angle of the segments SG measured in operation S140 may be 270°. In other words, the angle determined in operation S141, which is an operation of determining whether the angle of the corner bending is 2n times 45° (where n is an integer), based on the direction segment DR_SG of the segments SG, may be an even multiple of 45°. Therefore, operation S151 may be performed in the case of FIG. 5. It is assumed that corners of the target TA are divided into segments SG. In this case, the corners of the target TA may be divided into four segments SG in FIG. 5.

The start point of one segment SG may coincide with the end point of another segment SG neighboring in the direction segment DR_SG. According to an embodiment, the upper right vertex of the target TA may be the end point of a right segment SG and the start point of an upper segment SG.

According to an embodiment, the lower left vertex of the target TA may be the end point of a left segment SG and the start point of a lower segment SG. Therefore, in an example case in which operation S151 is performed, four first vertices VRTX1 may be set instead of eight, even though there are four segments SG in total. However, although the number of first vertices VRTX1 may be four, the number of second vertices VRTX2 added per first vertex VRTX1 may be two. In other words, the total number of second vertices VRTX2 added in operation S161 may be eight. The second vertex VRTX2 per vertex may be added 90° outward from the direction of progression.

According to an embodiment, at the upper right portion, the angle made by two second vertices VRTX2 and one first vertex VRTX1 is 90°. However, the second vertices VRTX2 are formed on the outside and are not located inside the target TA. After the second vertices VRTX2 is added, the fake segments FSG may be added in operation S170. Two fake segments FSG may be set orthogonally to each other per first vertex VRTX1. The start point of the fake segment FSG is the first vertex VRTX1 and the end point of the fake segment FSG is the second vertex VRTX2. Two fake segments FSG added from the first vertex VRTX1 may have start points that coincide with each other and end points that are different from each other.

The two fake segments FSG added from the first vertex VRTX1 have the same start point, but corresponding segments SG split in operation S120 may be different from each other. In other words, the first vertex VRTX1, which is the intersection of two added fake segments FSG, may be the start point of any one segment SG, but may be the end point of another segment SG. However, since the start point and the end point are coincident, the start points of the fake segments FSG appear to be the same, but the lengths of the added fake segments FSG may be the same.

An OPC-OP design layout may be formed by connecting the added fake segments FSG. The OPC-ed design layout OPC-OP may have a cross-like shape. The OPC-ed design layout OPC-OP may have corners corresponding to respective corners of the target TA. The longest corner of the OPC-ed design layout OPC-OP may have a length identical to the length of each corner of the target TA. Any corner except the longest corner of the OPC-ed design layout OPC-OP may correspond to the fake segment FSG.

Referring to FIG. 6 together with FIGS. 1 to 3, chopping layers CL are formed at corners of the target TA. In the case of FIG. 6, the direction segment DR_SG may be a counterclockwise direction. The corner where the chopping layer CL is formed is divided into the segments SG. The segment SG may also be referred to as a corner segment SG.

In FIG. 6, by performing operation S141 of determining whether the angle of the corner bending is 2n times 45° (where n is an integer), based on the direction segment DR_SG of the segments SG, it may be confirmed that the angle of every corner is 135°. Therefore, the angle may be an odd multiple of 45°. Therefore, operations S151 to S153 may be performed.

FIG. 6 illustrates an example case in which operation S151 is performed and operations S162 and S163 are performed sequentially. At the upper right portion of FIG. 6, a first start vertex VRTX1_S may be designated at the start point of the segment SG, and a first end vertex VRTX1_E may be designated at the end point of the segment SG.

In operation S151, since vertices are added to both ends (i.e., the start point and the end point) of one segment SG, two first vertices may be designated at both ends of the one segment SG. The same applies to the upper left portion of FIG. 6. Based on the direction segment DR_SG, the first start vertex VRTX1_S may be designated at the start point of the segment SG, and the first end vertex VRTX1_E may be designated at the end point of the segment SG.

According to an embodiment, operations S162 and S163 may be performed sequentially. In an example case in which operation S162 is performed, a second start vertex VRTX2_S may be added in the normal direction of the segment SG. In the case of FIG. 6, the start point of the fake segment FSG may not be a first vertex. The end point of the fake segment FSG may be a second vertex. According to an embodiment, the fake segment FSG may be added, starting from the OPC-ed design layout OPC-OP and extending to the second start vertex VRTX2_S.

According to an embodiment, the fake segment FSG may be added, starting from the OPC-ed design layout OPC-OP and extending to a second end vertex VRTX2_E. The second start vertex VRTX2_S may correspond to the first start vertex VRTX1_S.

In an example case in which operation S163 is performed, the second end vertex VRTX2_E may be added in the normal direction of the segment SG. The second end vertex VRTX2_E may correspond to the first end vertex VRTX1_E. The segment SG formed by connecting both ends of added fake segments FSG may have the same length as the segment SG having the corresponding first start vertex VRTX1_S and the corresponding first end vertex VRTX1_E at both ends.

The fake segments FSG starting from the first start vertex VRTX1_S and the first end vertex VRTX1_E designated in operation S151 at both ends of the segment SG may be parallel to each other and have the same length. In FIG. 6, in an example case in which an intersection of segments SG is called a corner, it may be stated that one fake segment FSG is added at each corner. It may be stated that two fake segments FSG are added, one at each end of the corner segment SG.

Referring to FIG. 7 together with FIGS. 1 to 3, the chopping layer CL is formed at a corner of the target TA. In the case of FIG. 6, the direction segment DR_SG may be a clockwise direction. The corner at which the chopping layer CL is formed is divided into the segments SG. The segment SG may also be referred to as the corner segment SG.

In FIG. 7, by performing operation S141, which is an operation of determining whether the angle of the corner bending is 2n times 45° (where n is an integer), based on the direction segment DR_SG of the segments SG, it may be confirmed that the angle of a first corner is 135° and the angle of a second corner is 215°. Therefore, the angle may be an odd multiple of 45°.

FIG. 7 illustrates an example case in which operation S153 is performed for the segment SG of the first corner and operation S163 is performed after operation S153. An example case in which operation S152 is performed for the segment SG of the first corner and operation S162 is performed after operation S152 is shown.

At the segment SG of the first corner, first start vertices VRTX1_S may be designated at the start point of the segment SG, and the first end vertex VRTX1_E may be designated at the end point of the segment SG. Although two first vertices are designated, a mode in which only the second end vertex VRTX2_E corresponding to the first end vertex VRTX1_E is added is set by operation S153. Only the second end vertex VRTX2_E is added by operation S163. The second end vertex VRTX2_E may be added in the normal direction of the segment SG.

According to an embodiment, the fake segment FSG may be added, starting from the OPC-ed design layout OPC-OP and extending to a second end vertex VRTX2_E. The second end vertex VRTX2_E may correspond to the first end vertex VRTX1_E. The second start vertex VRTX2_S corresponding to the first start vertex VRTX1_S is not added.

At the segment SG of the second corner, first start vertices VRTX1_S may be designated at the start point of the segment SG, and the first end vertex VRTX1_E may be designated at the end point of the segment SG. Although two first vertices are designated at both ends of the segment SG, a mode in which only the second start vertex VRTX2_S corresponding to the first start vertex VRTX1_S is added is set by operation S152. Only the second start vertex VRTX2_S is added by operation S162. The second start vertex VRTX2_S may be added in the normal direction of the segment SG.

According to an embodiment, the fake segment FSG may be added, starting from the OPC-ed design layout OPC-OP and extending to the second start vertex VRTX2_S. The second start vertex VRTX2_S may correspond to the first start vertex VRTX1_S. The second end vertex VRTX2_E corresponding to the first end vertex VRTX1_E is not added.

The OPC-ed design layout OPC-OP may be formed by connecting the fake segments SG added at the first corner and the second corner.

As illustrated in the OPC-ed design layout OPC-OP of FIGS. 5 to 7, the fake segments SG are added to corners of the target, corner segments, or corners where the segments SG are arranged, thereby facilitating the corner rounding control.

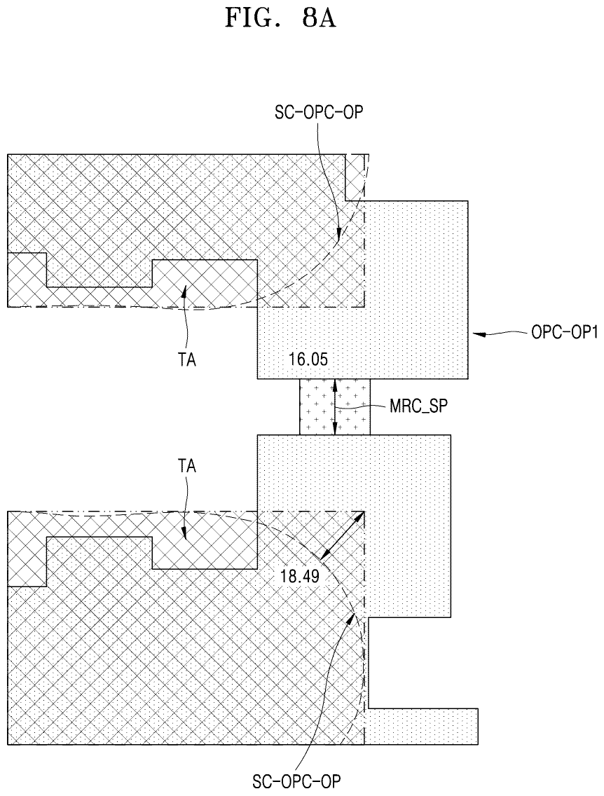

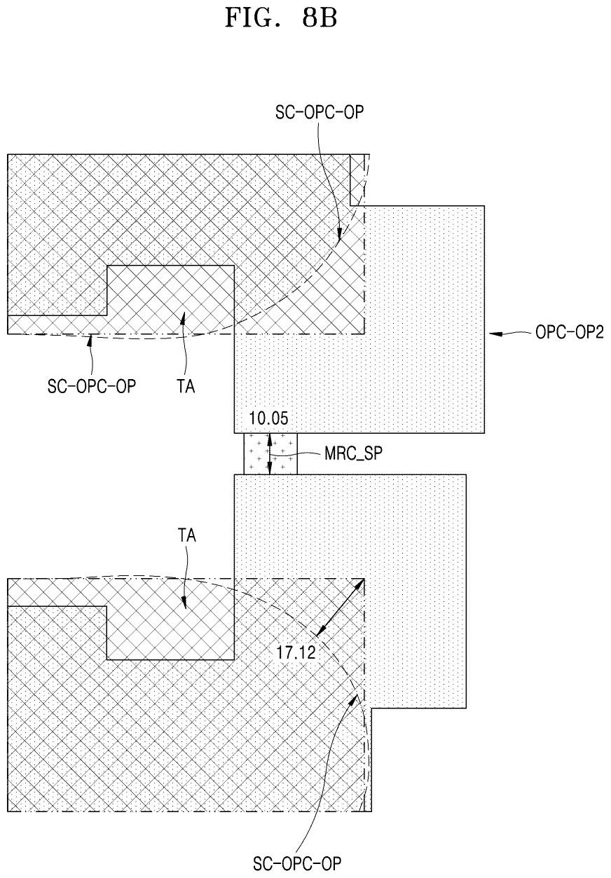

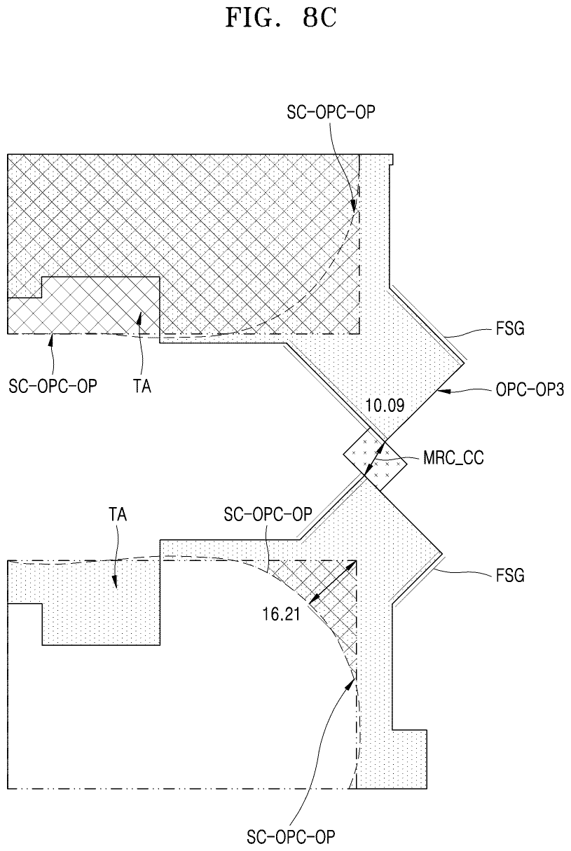

FIG. 8A is a conceptual diagram illustrating how OPC is performed while maintaining MRC.

Referring to FIG. 8A, the target TA is provided. After performing OPC, an OPC-ed design layout OPC-OP1 is formed. Operation S191 is performed based on the OPC-ed design layout OPC-OP1 to extract a simulation contour SC-OPC-OP. An extracted simulation contour SC-OPC-OP may be a curved line.

In an example case in which the Manhattan OPC is performed based on corners of the target TA, the corners of the OPC-ed design layout OPC-OP1 may become larger. However, even in this case, the interval between OPC-ed design layouts may not exceed the criteria of an MRC space MRC_SP of the OPC-ed design layout OPC-OP1.

The criteria of the MRC space MRC_SP may be the width of the space between OPC-ed design layouts OPC-OP1. According to an embodiment, the criteria of the MRC space MRC_SP may be about 16 nm. Respecting the criteria of the MRC space MRC_SP means that the width of the space between the OPC-ed design layouts OPC-OP1 is larger than the criteria.

In FIG. 8A, the space between the OPC-ed design layouts OPC-OP1 may be maintained at 16.05 nm, thereby respecting the criteria of the MRC space MRC_SP. The corner contour value of the OPC-ed design layout OPC-OP1 that respects the criteria of the MRC space MRC_SP may be 18.49 nm.

FIG. 8B is a conceptual diagram illustrating a result of performing the Manhattan OPC without maintaining MRC.

Referring to FIG. 8B, the target TA is provided. After performing OPC, an OPC-ed design layout OPC-OP2 is formed. Operation S191 is performed based on the OPC-ed design layout OPC-OP2 to extract a simulation contour SC-OPC-OP. An extracted simulation contour SC-OPC-OP may be a curved line. In an example case in which the Manhattan OPC is performed based on corners of the target TA, the corners of the OPC-ed design layout OPC-OP2 may become larger. The interval between OPC-ed design layouts may exceed the criteria of an MRC space MRC_SP of the OPC-ed design layout OPC-OP2.

The criteria of the MRC space MRC_SP may be the width of the space between OPC-ed design layouts OPC-OP2. According to an embodiment, the criteria of the MRC space MRC_SP may be about 16 nm. Respecting the criteria of the MRC space MRC_SP means that the width of the space between the OPC-ed design layouts OPC-OP2 is larger than the criteria.

In FIG. 8B, the space between the OPC-ed design layouts OPC-OP2 is 10.05 nm and is less than the criteria, thus corresponding to the case of not respecting the criteria of the MRC space MRC_SP. The corner contour value of the OPC-ed design layout OPC-OP2 that respects the criteria of the MRC space MRC_SP may be 17.12 nm. Since the OPC-ed design layout OPC-OP2 is expanded without respecting the criteria of the MRC space MRC_SP, the corner contour value of the target TA may be less than that in the case of FIG. 8A. As described in operation S192 of FIG. 2, the corner contour value of the target TA needs to be less than or equal to a reference value to satisfy the process condition and to not to perform OPC anymore. However, in the case of FIG. 8B, although the corner contour value of the target TA is small, the criteria of the MRC space MRC_SP is not respected.

FIG. 8C is a conceptual diagram illustrating a result of performing an OPC based on added fake segments in an OPC method, according to an embodiment.

Referring to FIG. 8C, the target TA is provided. After performing OPC, an OPC-ed design layout OPC-OP3 is formed. The OPC-ed design layout OPC-OP3 may pass through fake segments FSG added to each corner of the target TA. Operation S191 is performed based on the OPC-ed design layout OPC-OP3 to extract a simulation contour SC-OPC-OP. An extracted simulation contour SC-OPC-OP may be a curved line. In an example case in which the Manhattan OPC is performed based on corners of the target TA, the corners of the OPC-ed design layout OPC-OP2 may become less than that in FIGS. 8A and 8B. However, although the area of the corners of the OPC-ed design layout OPC-OP3 is relatively small, the corner rounding control for the corners may be increased.

For example, increasing corner rounding control means that the corners of the OPC-ed design layout OPC-OP3 are expressed similarly as the corners of the target TA. For the OPC-ed design layout OPC-OP3, MRC corner to corner MRC_CC may be measured.

The MRC corner to corner MRC_CC is a concept distinct from the criteria of MRC space MRC_SP and refers to the distance between corners of OPC-ed design layouts OPC-OP3 closest to each other.

In the case of FIG. 8C, since corner segments to not face each other in the space between the OPC-ed design layouts OPC-OP3, the criteria of the MRC space MRC_SP are not measured separately. Instead, it is determined based on whether the interval between OPC-ed design layouts respects the MRC corner to corner MRC_CC criteria. Respecting the criteria of the MRC corner to corner MRC_CC means that the width of the space between corners to the OPC-ed design layouts OPC-OP3 closest to each other is greater than the criteria. According to an embodiment, the criteria of the MRC corner to corner MRC_CC may be 10 nm.

In FIG. 8C, the MRC corner to corner MRC_CC, which is the distance between corners closest to each other, is 10.09 nm, thus respecting the criterion of the MRC corner to corner MRC_CC.

The corner contour value of the OPC-ed design layout OPC-OP3 that respects the criteria of the MRC corner-to-corner MRC_CC may be 16.21 nm. Since the fake segments FSG are added while maintaining the criteria of the MRC corner to corner MRC_CC, the corner contour value of the target TA may be less than that in FIGS. 8A and 8B. As described in operation S192 of FIG. 2, the corner contour value of the target TA needs to be less than or equal to a reference value to satisfy the process condition and to not to perform OPC anymore. In the case of FIG. 8C, it may be confirmed that the corner contour value of the target TA decreases while maintaining the criteria of the MRC corner to corner MRC_CC, thus being more advantageous for the corner contour than in FIGS. 8A and 8B.

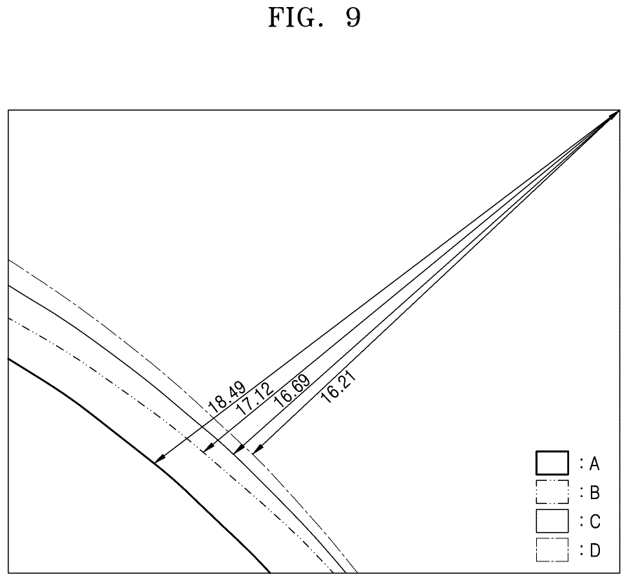

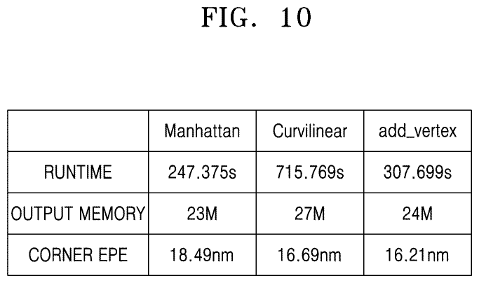

FIG. 9 is a conceptual diagram illustrating corner EPE values for respective cases. FIG. 10 is a table showing runtimes, output memories, and corner EPE values for respective cases.

Referring to FIG. 9 together with FIGS. 8A to 8C, the thick solid line A represents a case where Manhattan OPC is performed while respecting the criteria of the MRC space MRC_SP, a two-dotted chain line B represents a case where Manhattan OPC is performed without respecting the criteria of the MRC space MRC_SP, and a thin solid line C represents a case where curvilinear OPC is performed instead of Manhattan OPC.

In FIG. 9, a one-dot chain line D represents a case where Manhattan OPC is performed while respecting the criteria of MRC corner to corner MRC_CC by adding a vertex and adding a fake segment FSG extending to an added vertex according to an embodiment.

The numbers illustrated in respective cases A-D of FIG. 9 represent corner EPE values. For A, the corner EPE is 18.49 nm, which is the largest value. For B, the corner EPE is 17.12 nm, which is the second largest value. For C, it may be confirmed that the value of the corner EPE is 16.69 nm, which is less than those in A and B. For D, it may be confirmed that the value of the corner EPE is 16.21 nm, which is less than those of all other cases. Therefore, it may be confirmed that corner contour control is easiest in the case of D according to an embodiment.

Referring to FIG. 10, an example case in which only Manhattan OPC is performed while respecting the criteria of the MRC space MRC_SP is indicated by “Manhattan”. In other words, the case of FIG. 8A corresponds to the case of A of FIG. 9.

In FIG. 10, a result of performing curvilinear OPC is indicated by “Curvilinear”. This refers to the case of C of FIG. 9.

According to an embodiment, the example case in which Manhattan OPC is performed by adding vertices and fake segments and performing corner curve rounding is indicated as “add_vertex”. Runtimes, output memories, and corner EPEs for the following three cases will be compared.

For runtime, “Manhattan”, which represents the case of simply performing Manhattan OPC, showed 247.375 seconds, which is the shortest runtime. Next, “add_vertex” showed 307.699 seconds, which is about 20 seconds longer than that of “Manhattan”. “Curvilinear” showed 715.769 seconds, which is the longest runtime and is more than twice as long as those of the other two cases. In other words, it may be understood that the process time takes more than twice as much time to perform the OPC process on one wafer.

In the cases of output memories, “Manhattan,” which is a result of simply performing Manhattan OPC, needed 23 megabytes, which is the smallest amount of memory. Next, “add_vertex” needed 24 megabytes, which is about 1 megabyte more than that of “Manhattan”. It may be seen that “Curvilinear” needs 27 megabytes, which is the largest amount of memory and is larger than those of the other cases.

For the corner EPE, “Manhattan”, which is a result of simply performing Manhattan OPC, showed 18.49 nm, which is the largest corner EPE, and it may be confirmed that corner rounding control is the most difficult. Next, it may be seen that “Curvilinear” showed 16.69 nm, and “add_vertex” showed 16.21 nm.

Therefore, the case of “add_vertex” facilitates corner rounding control the most, and, although “Curvilinear” also facilitates corner rounding control than “Manhattan” does, the runtime of “Curvilinear” is much greater than those of the other cases, and the size of a needed memory is not optimized for the process as compared to those of the other cases. In contrast, since the runtime and the output memory of “add_vertex” are not significantly different from those of the “Manhattan”, it may be confirmed that “add_vertex” is optimized for the process.

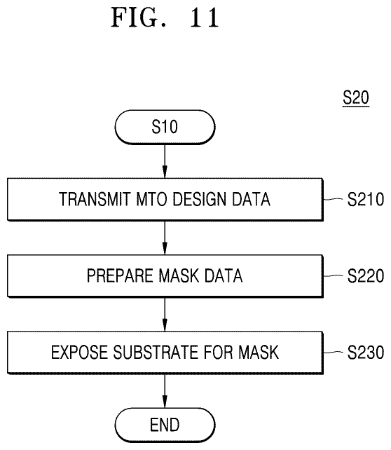

FIG. 11 is a schematic flowchart of operations of a mask manufacturing method including an OPC method, according to an embodiment.

Descriptions of FIG. 11 will be given below with reference to FIGS. 1 to 7 together. Referring to FIG. 11, a mask manufacturing method S20 including an OPC method (hereinafter, simply referred to as the ‘mask manufacturing method’) according to the embodiment sequentially may perform the OPC method S10. The OPC method S10 of FIG. 11 may include operations S191 and S192 of FIG. 2. The OPC method S10 of FIG. 11 may include operations S141, S151, S152, S153, S161, S162, and S163 of FIG. 3. Therefore, detailed descriptions thereof will be omitted.

According to an embodiment, after the final OPC-ed design layout is obtained, in operation S210, the method may include transmitting MTO design data to a mask production team. According to an embodiment, MTO may refer to handing over data regarding a final design layout obtained through an OPC method to the mask manufacturing team to request manufacturing of a mask. Therefore, in the mask manufacturing method according to the present embodiment, the MTO design data may refer to a final OPC-ed design or data regarding the final OPC-ed design layout. Such MTO design data may have a graphic data format used in electronic design automation (EDA) software, etc. For example, the MTO design data may have a data format including, but not limited to, Graphic Data System II (GDS2), Open Artwork System Interchange Standard (OASIS), etc.

In operation S220, the method may include performing mask data preparation (MDP). The MDP may include, for example, i) format conversion, called fracturing, ii) augmentation of barcodes for mechanical reading, a standard mask pattern for inspection, a job deck, etc., and iii) automatic and manual verification. Here, a job-deck may refer to generation of a text file regarding a series of instructions such as arrangement information of multiple mask files, a standard dose, and a speed or a method of exposure.

The format conversion, i.e., fracturing, may refer to a process of dividing MTO design data into respective regions and converting the MTO design data to a format for electron beam exposure equipment. The fracturing may include data manipulation, such as scaling, sizing of data, rotating of data, reflecting a pattern, and inverting colors. During a conversion process through fracturing, data regarding a large number of systematic errors that may occur somewhere during transmission from design data to an image on a wafer may be corrected.

The process of correction of data regarding systematic errors is called mask process correction (MPC) and may include, for example, a task for adjusting a line width called CD adjustment and a task for improving pattern placement precision. Therefore, the fracturing may contribute to improving the quality of a final mask and may also be a process that is performed in advance for mask process correction. Here, the systematic errors may be caused by distortions occurring in an exposure process, a mask development and etching process, and a wafer imaging process.

In addition, the MDP may include the MPC. As described above, the MPC refers to a process of correcting errors that occur during an exposure process, that is, systematic errors. Here, the exposure process may be an overall concept that includes electron beam writing, development, etching, baking, etc. Also, data processing may be performed prior to the exposure process. The data processing is a preprocessing process regarding mask data and may include grammar check for mask data, exposure time prediction, etc.

According to an embodiment, after mask data is prepared, in operation S230, a mask substrate is exposed based on the mask data. Here, the exposure may mean, for example, electron beam writing. Here, the electron beam writing may be performed, for example, through a gray writing method using a multi-beam mask writer (MBMW). Also, the E-beam writing may also be performed using variable shape beam (VSB) exposure equipment.

Meanwhile, after the MDP, a process of converting the mask data into pixel data may be performed before an exposure process. Pixel data is data directly used for actual exposure and may include data regarding a shape to be exposed and data regarding the dose assigned to each shape. Here, the data regarding a shape may be bit-map data obtained by converting shape data, which is vector data, through rasterization or the like.

After the exposure process, a series of processes may be performed to complete a mask. The series of processes may include, for example, development, etching, and cleaning. Also, a series of processes for manufacturing a mask may include a metrology process, a defect inspection process, or a defect repair process. Furthermore, the series of processes for manufacturing a mask may include a pellicle application process. Here, the pellicle application process may refer to a process of attaching pellicles to a mask surface to protect a mask from subsequent contamination during delivery and during the useful life of the mask when it is confirmed that there are no contaminant particles or chemical stains through final cleaning and inspection.

In a mask manufacturing method according to the present embodiment, the OPC method may include an operation of adding vertices and an operation of adding fake segments, as described above.

While the inventive concept has been particularly shown and described with reference to embodiments thereof, it will be understood that various changes in form and details may be made therein without departing from the spirit and scope of the following claims.

What is claimed is:

1. An optical proximity correction (OPC) method comprising:
obtaining an OPC target design layout;
dividing one or more edges of the OPC target design layout into a plurality of segments;
setting a direction of progression of the plurality of segments;
measuring angles of the plurality of segments with respect to the direction of progression;
setting a mode for adding vertices based on the angles of the plurality of segments;
adding the vertices based on the mode;
adding at least one fake segment extending to an added vertex, among the vertices; and
performing OPC based on the at least one fake segment.

2. The OPC method of claim 1,
wherein the measuring the angles of the plurality of segments with respect to the direction of progression comprises determining whether an angle of a corner bending is 2n times 45°, where n is an integer, based on the direction of progression of the plurality of segments.

3. The OPC method of claim 2, wherein the mode for adding the vertices comprises one of:
a start mode for adding a vertex to a start point of a segment, based on the direction of progression of the plurality of segments;
an end mode for adding a vertex to an end point of the segment, based on the direction of progression of the plurality of segments; and
a dual mode for adding vertices to the start point and the end point of the segment.

4. The OPC method of claim 3, wherein, based on the start point and the end point of each of the plurality of segments being first vertices and a dissection point added in the adding of the vertices being a second vertices, the at least one fake segment extends to a second vertex corresponding to a first vertex,
wherein the first vertex is or corresponds to one of the first vertices, and the second vertex is or corresponds to one of the second vertices.

5. The OPC method of claim 4, wherein, based on the mode for adding the vertices being the dual mode, a length of a segment connecting adjacent second vertices, among the second vertices, is equal to a length of a segment connecting the first vertices corresponding to the adjacent second vertices.

6. The OPC method of claim 3, wherein, based on the angle of the corner bending being 2n times 45°, the mode for the vertices is set to the dual mode, and
the adding of the vertices comprises adding two dissection points, each at 90 degrees to the outside of the direction of progression at a corner.

7. The OPC method of claim 3, wherein, based on the angle of the corner bending being 2n times 45°, a start point of one segment coincides with an end point of another neighboring segment in the direction of progression of the plurality of segments.

8. The OPC method of claim 3, wherein, based on the angle of the corner bending being different than 2n times 45°, the mode for the vertices is set to the dual mode, and
the adding of the vertices comprises adding one dissection point to each of the start point and the end point of the segment sequentially in a normal direction of the segment.

9. The OPC method of claim 3, wherein, based on the angle of the corner bending being different than 2n times 45°, the mode for adding the vertex is set to one of the start mode and the end mode, and,
based on a set mode being the start mode, the adding of the vertices is adding one dissection point to the start point of the segment in a normal direction of the segment.

10. The OPC method of claim 3, wherein, based on the angle of the corner bending being different than 2n times 45°, the mode for adding the vertex is set to one of the start mode and the end mode, and,
based on a set mode being the end mode, the adding of the vertices is adding one dissection point to the end point of the segment in a normal direction of the segment.

11. The OPC method of claim 1, further comprising:
based on a Manhattan optical proximity corrected layout, extracting simulation contours; and
determining whether an edge placement edge (EPE) value of an extracted simulation contour is less than or equal to a set reference value.

12. An optical proximity correction (OPC) method comprising:
obtaining an OPC target design layout;
dividing one or more edges of the OPC target design layout into a plurality of segments;
setting a direction of progression of the plurality of segments;
measuring angles of the plurality of segments with respect to the direction of progression;
setting a mode for adding vertices based on the angles of the plurality of segments;
adding the vertices based on the mode;
adding at least one fake segment extending to an added vertex, among the vertices; and
performing a Manhattan OPC based on the least one fake segment,
wherein the at least one fake segment is added in a normal direction to one of both ends, a start point, and an end point of a segment, among the plurality of segments, and
wherein the measuring of the angles of the segments with respect to the direction of progression comprises determining whether an angle of a corner bending is 2n times 45°, where n is an integer, based on the direction of progression of the segments.

13. The OPC method of claim 12, wherein first vertices are located within the plurality of segments,
second vertices are dissection points added in the adding of the vertices according to the set mode, and
the fake segment extends to a second vertex corresponding to a first vertex.

14. The OPC method of claim 12, wherein, based on the angle of the corner bending being an even multiple of 45°, two fake segments are added at a corner where the segment intersects, and
wherein the two fake segments are orthogonal to each other and have a same length.

15. The OPC method of claim 12, wherein, based on the angle of the corner bending being an odd multiple of 45°, a first fake segment is added to the start point of the segment and a second fake segment is added to the end point of the segment, and
wherein the first fake segment and the second fake segment are parallel to each other and have a same length.

16. The OPC method of claim 12, wherein the mode for adding the vertices comprises one of:
a start mode for adding a vertex to a start point of a segment, based on the direction of progression of the plurality of segments;
an end mode for adding a vertex to an end point of the segment, based on the direction of progression of the plurality of segments; and
a dual mode for adding vertices to the start point and the end point of the segment.

17. The OPC method of claim 16, wherein, based on the angle of the corner bending being an odd multiple of 45°, the mode for adding the vertex is set to one of the start mode and the end mode, and,
based on a set mode being the start mode, the at least one fake segment is added to the start point of the segment.

18. The OPC method of claim 16, wherein, based on the angle of the corner bending being an odd multiple of 45°, the mode for adding the vertex is set to one of the start mode and the end mode, and
wherein based on a set mode is the end mode, the at least one fake segment is added to the end point of the segment.

19. A mask manufacturing method comprising:
obtaining an OPC target design layout;
dividing one or more edges of the OPC target design layout into a plurality of segments;
setting a direction of progression of the plurality of segments;
measuring angles of the plurality of segments with respect to the direction of progression;
setting a mode for adding vertices based on the angles of the plurality of segments;
adding the vertices based on the mode;
adding at least one fake segment extending to an added vertex, among the vertices;
performing a Manhattan OPC based on the at least one fake segment;
transmitting data regarding a final optical proximity corrected Manhattan design layout as mask tape-out (MTO) design data;
preparing mask data based on the MTO design data; and
performing exposure on a mask substrate, based on the mask data,
wherein the at least one fake segment is added in a normal direction of one of both ends, a start point, and an end point of a segment, among the plurality of segments,
wherein the measuring the angles of the plurality of segments with respect to the direction of progression comprises determining whether an angle of a corner bending is 2n times 45°, where n is an integer, based on the direction of progression of the plurality of segments,
wherein the mode for adding the vertices comprises one of:
a start mode for adding a vertex to a start point of a segment, based on the direction of progression of the segments;
an end mode for adding a vertex to an end point of the segment, based on the direction of progression of the segments; and
a dual mode for adding vertices to the start point and the end point of the segment,
wherein based on the start point and the end point of each of the plurality of segments being first vertices and dissection points added in the adding of the vertices being second vertices, the at least one fake segment extends to a second vertex corresponding to a first vertex, and
wherein the first vertex is or corresponds to one of the first vertices, and the second vertex is or corresponds to one of the second vertices.

20. The mask manufacturing method of claim 19, wherein, based on the mode for adding the vertices is the dual mode, a length of a segment connecting adjacent second vertices from among the second vertices is equal to a length of a segment connecting the first vertices corresponding to the second vertices.
